(19) United States
(12) Patent Application Publication
(10) Pub. No.: US 2015/0047784 A1
(43) Pub. Date: Feb. 19, 2015

(54) METHOD FOR APPLYING A TEMPORARY BONDING LAYER

(71) Applicant: EV GROUP E. THALLNER GMBH, ST. FLORIAN AM INN (AT)

(72) Inventor: Jurgen Burggraf, Scharding (AT)

(73) Assignee: EV GROUP E. THALLNER GMBH, ST. FLORIAN AM INN (AT)

(21) Appl. No.: 14/388,107

(22) PCT Filed: Dec. 16, 2013
(86) PCT No.: PCT/EP2013/076629

§ 371 Date: Sep. 25, 2014

(30) Foreign Application Priority Data
Dec. 21, 2012 (DE) 102012112989.4

(51) Int. Cl. H01L 21/673; C25D 5/48; C23C 16/56; C23C 16/01; C23C 16/40

(52) U.S. Cl. CPC H01L 21/673; C23C 16/01; C23C 16/402; C23C 16/56; C25D 5/48
USPC 156/308.2; 427/248.1; 427/331; 427/256; 205/220

(57) ABSTRACT

A method for applying a temporary bonding layer to a carrier wafer for temporary joining to a product wafer by fusion bonding or anodic bonding, said method comprising:
applying a temporary bonding layer which is suitable for fusion bonding or anodic bonding to the carrier wafer and
modifying the temporary bonding layer during and/or after application such that the temporary connection of the temporary bonding layer can be broken.

### FIELD OF THE INVENTION

This invention relates to a method for applying a temporary bonding layer to a carrier wafer for temporary bonding with a product wafer by fusion bonding or anodic bonding.

### BACKGROUND OF THE INVENTION

In the semiconductor industry, it is necessary to develop carrier technologies in order to be able to fix, transport and process product wafers. A hitherto unsolved problem is the temporary fixing of a wafer onto a carrier wafer for high temperature applications. In the known temporary bonding technologies, materials are used which at least largely lose their adhesion force above a certain temperature. The object of this invention is therefore to devise a method for applying a temporary bonding layer to a carrier wafer for temporary joining to a product wafer which can be used for higher temperatures than known to date.

This object is achieved with the features of Claim 1. Advantageous developments of the invention are given in the dependent claims. All combinations of at least two of the features given in the specification, the claims and/or in the figures fall within the scope of the invention. For given values ranges, values which lie within the indicated limits should be considered disclosed as boundary values and able to be claimed in any combination.

The invention is based on the concept of using a material (or a combination of materials) which is suitable for fusion bonding or for anodic bonding for the application of a temporary bonding layer and ensuring the property as a temporary bonding layer by a modification of the temporary bonding layer during or after application taking place, such that a connection produced by a fusion bond or anodic bond to a product wafer can be broken again with corresponding, especially radical detachment means. The aforementioned measure allows the use of carriers at much higher temperatures than in the past so that treatment of the product wafer at much higher temperatures than in the prior art is possible. As a result, temperature range accessible with carrier technology for bonding/debonding technologies is thus greatly expanded. Thus, it is possible to carry out process steps between the application of the temporary bonding layer and the detachment which in the past could only be carried out in substrates joined by permanent bonds.

The present invention is based on depositing a temporary bonding layer, in particular a layer comprised preferably solely of SiO₂, onto a carrier wafer, especially a Si layer. According to the invention, deposition methods can be PVD and/or CVD processes and/or sol-gel processes and/or electrochemical deposition and/or wet chemical deposition. The temporary bonding layer is modified by a structuring of the layer or by changing the microstructure of the temporary bonding layer. The later detachment of the temporary bonding layer from the product substrate and the later detachment of the product substrate from the carrier substrate is enabled by the modification.

According to one embodiment of the invention, the modification takes place by surface treatment, especially by structuring and/or by changing the microstructure of the temporary bonding layer.

Preferably, the surface treatment takes place such that channels which penetrate the temporary bonding layer parallel to the carrier wafer are formed. In this way, the temporary bonding layer can be dissolved with solvents as detachment agents, which solvents act chemically, preferably selectively on the temporary bonding layer.

In another advantageous embodiment of the invention, porosity of the temporary bonding layer is provided for modification of the temporary bonding layer when the temporary bonding layer is applied by means of CVD methods and that gases are enclosed in the pores of the temporary bonding layer by exposure to a gas during the CVD process. The properties of the enclosed gases can then be used for breaking the connection. The porosity, in conjunction with the disclosed channels, can also facilitate and support the access of the detachment agents, mainly when it involves open porosity. Therefore a combination of porous material and channels is contemplate according to the invention.

According to the invention, the gases, can be all types of monoatomic, biatomic or polyatomic gases, preferably in any case helium, argon, neon, hydrogen, oxygen, nitrogen, carbon dioxide, carbon monoxide, water vapor, HCL, sulfuric acid, hydrofluoric acid, nitric acid, phosphoric acid and all organic acids.

In another embodiment, a glass carrier wafer and a silicon temporary bonding layer or a silicon carrier wafer and a glass temporary bonding layer are used. Anodic bonding takes place preferably in a temperature range between 0° C. and 800° C., preferably between 100° C. and 700° C., more preferably between 200° C. and 600° C., most preferably between 300° C. and 500° C. The absolute amount of the voltage between the anode and cathode in anodic bonding is in the range between 0 V and 1000 V, preferably between 100 V and 900 V, more preferably between 200 V and 800 V, most preferably between 300 V and 700 V, most preferably of all between 400 V and 600 V.

As further method steps in the invention, there are the following:
after application and modification, temporary bonding to the product substrate with bond force F_{b} and/or
after temporary bonding, processing of the product substrate and during and/or after the processing, weakening of the interface between the temporary bonding layer and product substrate or glass substrate and product substrate for detachment of the product substrate.

The bond force is between 0 N and 100000 N, preferably between 0 N and 10000 N, more preferably between 0 N and 1000 N, most preferably between 0 N and 100 N.

In the most preferred embodiment of a temporary bonding layer of SiO₂ and a carrier wafer of silicon, bonding takes place even at room temperature without the action of a force. The covalent bonding which arises between the Si surface of the carrier wafer and the SiO₂ surface of the temporary bonding layer can be improved by a corresponding surface treatment before bonding. Plasma treatment, wetting with DI (deionized) water or chemical cleaning would be conceivable for surface modification.

### BRIEF DESCRIPTION OF THE DRAWINGS

Other advantages, features and details of the invention will become apparent from the following description of preferred exemplary embodiments using the drawings.

FIGS. 1a to 1f show six method steps according to a first embodiment of the claimed method;

FIGS. 2a to 2f show six method steps according to a second embodiment of the claimed invention;

FIG. 3 schematically illustrates a third embodiment of the method.

### DETAILED DESCRIPTION OF THE PREFERRED EMBODIMENTS

In the figures, advantages and features of the invention are labeled with reference numbers which identify them according to embodiments of the invention, and components and features with the same function and/or a function with the same action can be labeled with identical reference numbers.

In the first embodiment of the invention, a carrier wafer 1 is first coated with a temporary bonding layer 2. The temporary bonding layer 2 is preferably SiO₂. The coating can take place by all known coating methods. Preferably, the coating takes place by PVD, CVD or electrochemical deposition. The thickness of the temporary bonding layer 2 depends on different parameters, but is between 1 nm and 1 mm. The thickness of the temporary bonding layer 2 is between 1 nm and 1 mm, preferably between 10 nm and 100 μm, more preferably between 100 nm and 10 μm, most preferably between 1 μm and 5 μm. The temporary bonding layer 2 is structured by methods which are known to one skilled in the art in the field.

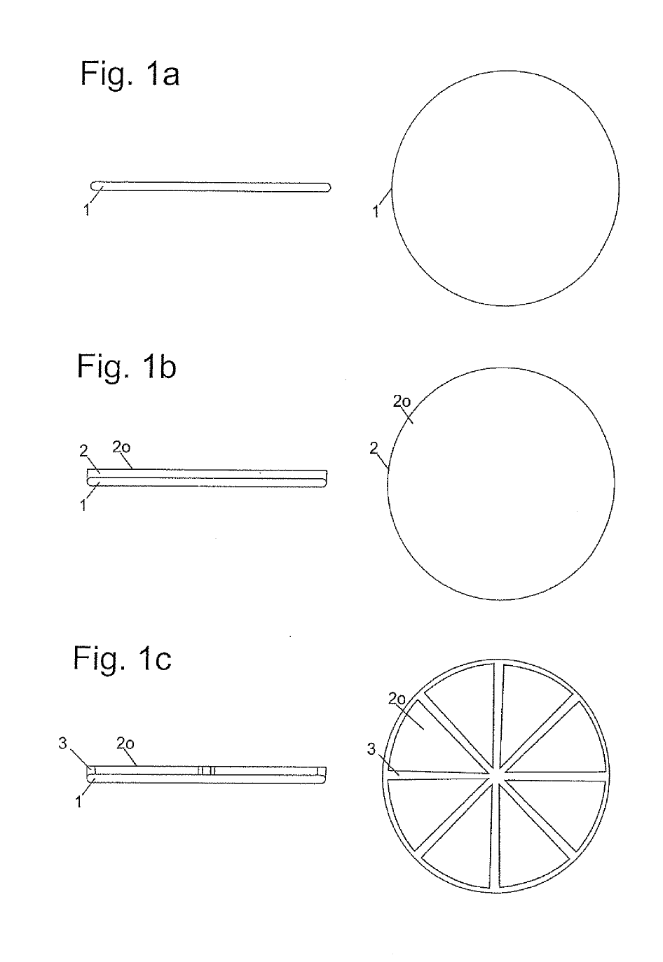

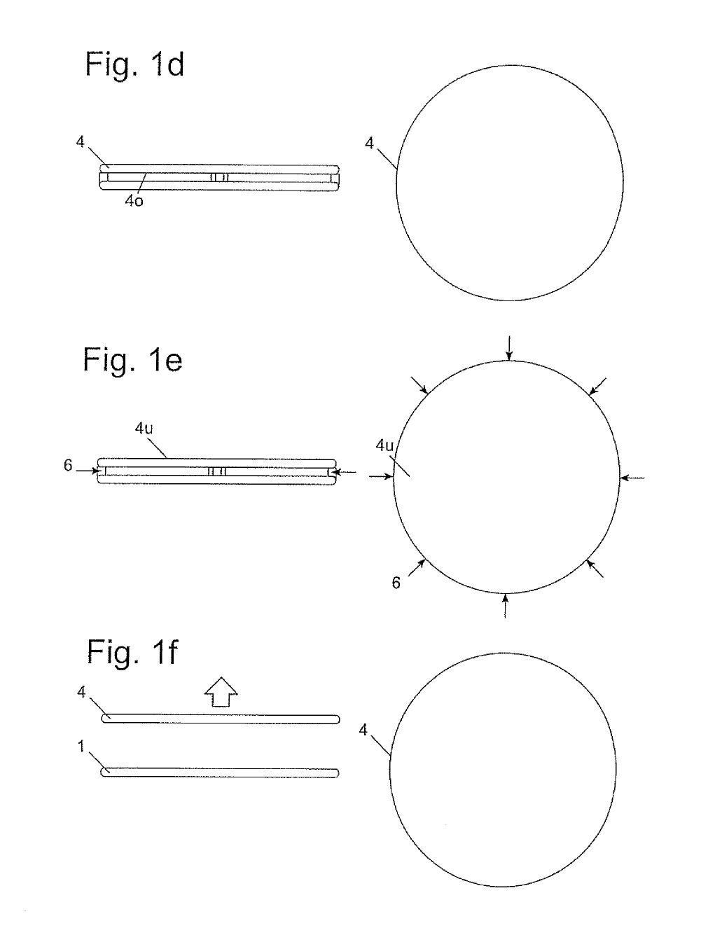

FIG. 1c shows by way of example a structured temporary bonding layer 2 with channels 3. These channels 3 can be produced, for example, by known mask techniques, lithography, masking and later etching with acids and/or bases and/or by correspondingly suitable chemicals.

Direct production of the structured temporary bonding layer 2 by means of shadow masks during the deposition process is also contemplated in the invention. In this respect, the shadow masks mask those regions on which the material is not to settle during the deposition process. Use of shadow masks saves subsequent masking and etching of the temporary bonding layer 2 which has been applied over the entire surface.

Etching takes place with hydrofluoric acid (hydrogen fluoride, HF) in the liquid and/or vapor state. Admission through the channels 3 and/or through the existing pores takes place especially rapidly in the vapor phase.

Other acids which can be used include sulfuric acid, hydrochloric acid, nitric acid, phosphoric acid, and all organic acids.

Alternatively the use of a known mixture of several chemicals, for example aqua regia, piranha (H₂SO₄+H₂O₂), and a mixture of hydrofluoric acid and nitric acid is also contemplated.

Basic substances, for example KOH, TMAH (tetramethylammonium hydroxide) and/or EDP (ethylene diamine pyrocatechol) are also used as etching media.

The etching rate of the SiO₂ when attacked by a 44% KOH solution at roughly 85° C. is roughly 14 Angstrom/min.

The etching rate of the SiO₂ when attacked by a 25% TMAH solution at roughly 80° C. is roughly 2 Angstrom/min.

The etching rate of the SiO₂ when attacked by an EDP solution at roughly 115° C. is roughly 2 Angstrom/min.

Due to the low etching rates, therefore higher concentration and/or higher operating temperatures are claimed. The solution used has a concentration greater than 20%, preferably greater than 40%, more preferably greater than 60%, most preferably greater than 80%, most preferably of all greater than 99%.

The etching temperature used as claimed in the invention is greater than 25° C., preferably greater than 50° C., more preferably greater than 100° C., most preferably greater than 200° C., most preferably of all greater than 400° C.

The surface 4o of a product wafer 4 can now be bonded to the surface 2o of the temporary bonding layer 2. In contrast to bonding with cements, in which polymers are generally used, the bond here takes place between the temporary bonding layer 2 which is designed for high temperature, preferably SiO₂, and the surface 4o of the product wafer 4. Fusion bonding technologies and anodic bonding technologies are known to one skilled in the art in the field. The fusion bond or the anodic bond is so strong that the back 4u must be processed. For example, back-thinning of the product wafer 4 is named. The fusion bond in the ideal case takes place at room temperature without the action of a force, i.e., solely by simple contact of the surface of the temporary bonding layer 2 with the surface of the carrier wafer 1. The anodic bond generally takes place in conjunction with application of a force and higher temperatures.

After processing of the product wafer 4, the product wafer 4 can again be detached from the temporary bonding layer 2 by a chemical 6 penetrating through the channels 3 and dissolving the temporary bonding layer 2 or at least weakening the interface between the surface 4o of the product wafer 4 and the surface 2o of the temporary bonding layer 2 (FIGS. 1d to 1f). The channels 3 are used predominantly for better admission of the chemical to the temporary bonding layer 2. The chemical dissolves the temporary bonding layer 2 and allows the separation of the product wafer 4 from the carrier wafer 1. The carrier wafer 1 can be re-used. If residues of the temporary bonding layer 2 should be found on the carrier wafer 1, the carrier wafer 1 can be cleaned as claimed in the invention.

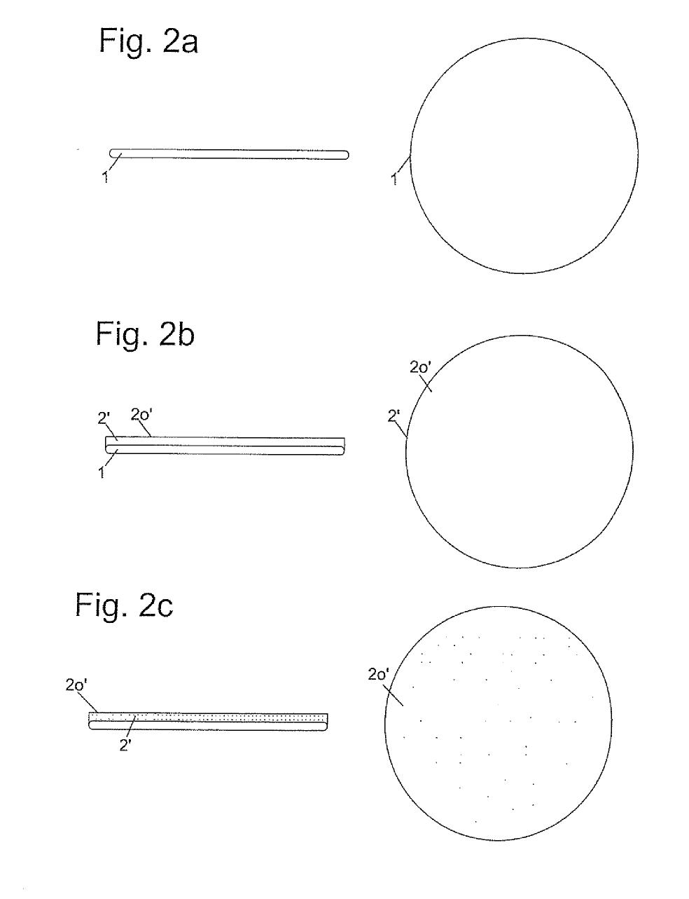

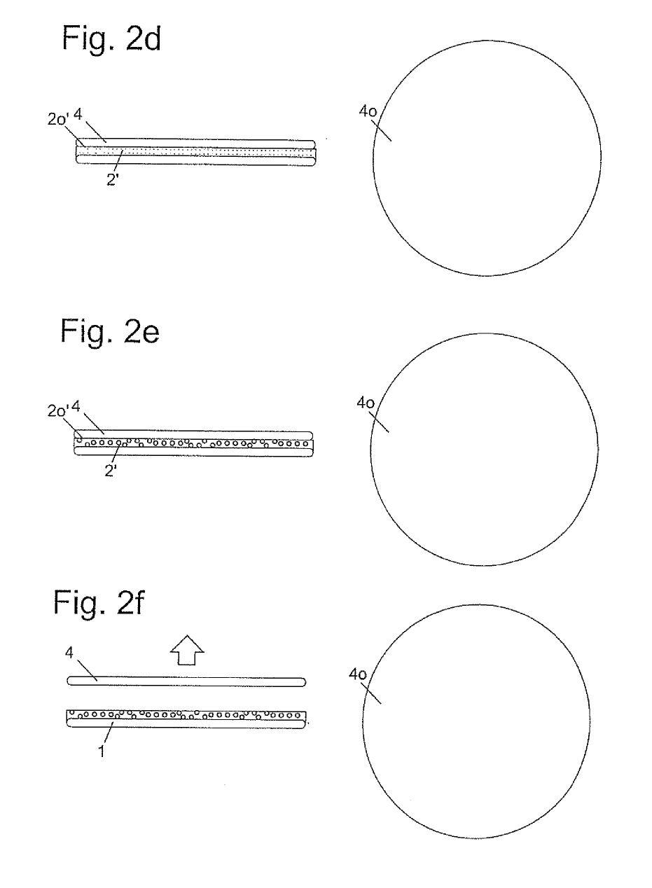

In another embodiment of the present invention (FIGS. 2a-c), the temporary bonding layer 2′ is applied to the carrier wafer 1 by a coating process, preferably a CVD coating process. When a CVD coating process is used, the deposited layer already has a correspondingly high porosity. If other coating processes are used, a corresponding porosity must be produced by known processes. Various gases can be introduced into this porosity or are already enclosed in the coating process. The product wafer 4 is welded to the temporary bonding layer 2′ by a fusion bonding process. The product wafer 3 can be processed accordingly on its back. The gases in the temporary bonding layer 2′ expand by heating above a critical temperature Tk. This expansion of the volume leads to an at least predominant breaking-open of the temporary bonding layer 2′ and/or to a weakening of the interface between the surface 2o′ of the temporary bonding layer 2′ and the surface 4o of the product substrate 4 and to the possibility of removing the product wafer 4 from the carrier wafer 1, more exactly from the temporary bonding layer 2′. The outgassing must not lead to complete delamination of the interface. It is sufficient if the outgassing process leads to a weakening of the interface (temporary bonding layer 2′) and the two wafers 1, 4 are separated from one another by a later, mechanical separation process (FIGS. 2d to 2f). Accordingly the critical temperature Tk can very probably also lie in the temperature interval in which the product wafer 4 is being processed so that the outgassing takes place during the processing of the product wafer 4.

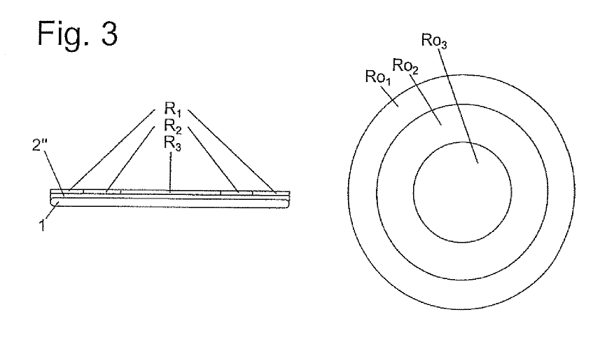

In another embodiment (FIG. 3), surfaces Rₒₓ (where X is 1, 2 and 3) of different regions Rₓ (where X is 1, 2 and 3) of a temporary bonding layer 2″, which has been applied over the entire surface, preferably a SiO₂ layer, are exposed to different physical and/or chemical processes so that the subsequent fusion bonding process leads to bond forces of different strength in the individual regions Rₓ. Such processes, may be, by way of example and not limitation: plasma processes, coating processes, processes for changing the surface roughness.

In another embodiment the product substrate 4 is bonded to a carrier wafer 1 by an anodic bonding method. In doing so, the formation of the siloxane compound Si—O—Si, caused by cations and anion transport, leads to a welding of the product substrate 4 to the carrier substrate 1 via the temporary bonding layer 2. In a first embodiment the carrier substrate 1 is a glass carrier substrate 1 and the temporary bonding layer 2, 2′, 2″ consists at least predominantly, preferably completely, of silicon. In a second embodiment the carrier substrate 1 is a silicon substrate 1 and the temporary bonding layer 2, 2′, 2″ consists at least predominantly, preferably completely, of glass. The temporary bonding layer 2, 2′, 2″ can be pretreated in the same manner as the SiO₂ layer from the other embodiments as claimed in the invention.

### REFERENCE NUMBER LIST

1 carrier wafer

2, 2′, 2″ temporary bonding layer

2o, 2o′, 2o″ surface

3 channels

4 product wafer

4o surface

4u back

6 solvent

Rₓ regions

Rₒₓ surfaces

1. A method for applying a temporary bonding layer to a carrier wafer for temporary bonding to a product wafer by fusion bonding or anodic bonding, said method comprising:
applying a temporary bonding layer which is suitable for fusion bonding or anodic bonding to the carrier wafer and
modifying the temporary bonding layer during and/or after application such that the temporary bonding of the temporary bonding layer can be broken.

2. The method as claimed in claim 1, wherein the step of modifying takes place by surface treatment by changing the microstructure of the temporary bonding layer.

3. The method as claimed in claim 1, wherein the step of applying takes place by CVD and/or PVD processes or electrochemical deposition.

4. The method as claimed in claim 1, wherein the temporary bonding layer is comprised of SiO₂.

5. The method as claimed in claim 1, wherein the step of modifying encompasses a formation of channels which penetrate the temporary bonding layer parallel to the carrier wafer.

6. The method as claimed in claim 1, wherein there is porosity of the temporary bonding layer for modification of the temporary bonding layer when the temporary bonding layer is applied by means of CVD methods and gases are enclosed in the pores of the temporary bonding layer by exposure to a gas during the CVD process.

7. The method as claimed in claim 1, wherein after application and modification a temporary bonding of the carrier wafer to the product wafer with a bond force F_{b} takes place by fusion bonding.

8. The method as claimed in claim 7, wherein after the temporary bonding, the product wafer is processed and during and/or after processing a weakening of the temporary bonding layer for detachment of the product wafer takes place.
